(19) United States
(12) Patent Application Publication
(10) Pub. No.: US 2024/0091961 A1
(43) Pub. Date: Mar. 21, 2024

(54) SUCTION NOZZLE AND COMPONENT MOUNTER

(71) Applicant: FUJI CORPORATION, Chiryu (JP)

(72) Inventor: Jinya IMURA, Toyoake-shi (JP)

(73) Assignee: FUJI CORPORATION, Chiryu (JP)

(21) Appl. No.: 18/351,654

(22) Filed: Jul. 13, 2023

(30) Foreign Application Priority Data
Sep. 16, 2022 (JP) 2022-148045

(51) Int. Cl. B25J 15/06

(52) U.S. Cl. CPC B25J 15/0683

(57) ABSTRACT

A suction nozzle includes a nozzle tip portion formed in a tubular shape, an elastic tubular member that is detachably provided on an outer periphery of the nozzle tip portion, and that extends in an extending direction of the nozzle tip portion from an opening portion of the nozzle tip portion, the elastic tubular member being configured to elastically deform to an uneven shape of a pickup surface of the component when a tip surface thereof is pressed against the pickup surface, and at least one abutting member having an abutting surface configured to abut against the pickup surface when the tip surface is pressed against the pickup surface and the elastic tubular member is elastically deformed, the abutting surface being disposed between the tip surface and the opening portion in the extending direction of the nozzle tip portion or at the same position as the opening portion.

### TECHNICAL FIELD

The present specification relates to a suction nozzle for performing a pickup process and a mounting process of a component to be mounted on a board, and a component mounter including the suction nozzle.

### BACKGROUND ART

A technique for mass-producing board products by performing board work on a board on which a circuit pattern is formed has become widespread. A typical example of a board work machine that performs the board work is a component mounter that performs component mounting work. In general, the component mounter includes a suction nozzle that performs a pickup process and a mounting process of a component by supplying negative pressure air, and a mounting head that moves in two horizontal directions while holding the suction nozzle. Here, various components, which are pickup targets, include components having an uneven shape on a pickup surface.

For example, in a board product used in a smartphone or the like, an interposer component (sometimes referred to as an interposer board) having a large number of hemispherical bumps (protrusion shape) on a front surface and a rear surface is frequently used. In a case where the pickup process of the interposer component is performed using an ordinary suction nozzle having a flat tip surface, a leak of negative pressure air occurs between the bumps (recessed shape), so that a pickup state is unstable. Therefore, special mounting heads in which the negative pressure does not easily decrease are used, but the special mounting heads are expensive. An example of technology related to this type of suction nozzle is disclosed in Patent Literature 1.

Patent Literature 1 discloses a component mounter including a suction nozzle with a pad that picks up a component with negative pressure air supplied while keeping an outer peripheral edge of an opening portion of a suction pad at a lower end portion in close contact with the component, and a pickup guide including a protruding portion that protrudes downward from the suction pad and that abuts against the component to hold the component in a constant pickup posture. According to this, it is possible to reliably and stably pick up a component having fine undulations on an upper surface (pickup surface).

### PATENT LITERATURE

Patent Literature 1: JP-A-2002-178287

### BRIEF SUMMARY

### Technical Problem

Incidentally, in the configuration of Patent Literature 1, since the outer peripheral edge of a sucking disk-shaped opening portion of the suction pad is bent and adheres to the component, it is possible to perform the reliable pickup process even though the pickup surface of the component has rough and fine undulations. However, since the outer peripheral edge of the opening portion is in line contact with the component, the suction pad can adhere to the fine undulations, but it cannot adhere to a non-fine uneven shape represented by a bump of the interposer component. In a case where the pickup process of the interposer component is attempted using the configuration of Patent Literature 1, since the leak of the negative pressure air is remarkable, it is difficult to pick up the interposer component, or the pickup state is unstable even though the interposer component can be picked up.

Therefore, it is an object of the present specification to provide a suction nozzle capable of reliably and stably picking up a component having an uneven shape on a pickup surface.

### Solution to Problem

The present specification discloses a suction nozzle that is supplied with negative pressure air to pick up a component, the suction nozzle includes at least one nozzle tip portion formed in a tubular shape, an elastic tubular member that is detachably provided on an outer periphery of the nozzle tip portion, and that extends in an extending direction of the nozzle tip portion from an opening portion of the nozzle tip portion, the elastic tubular member being configured to elastically deform to conform to an uneven shape of a pickup surface of the component when a tip surface thereof is pressed against the pickup surface, and at least one abutting member having an abutting surface configured to abut against the pickup surface when the tip surface is pressed against the pickup surface and the elastic tubular member is elastically deformed, the abutting surface being disposed between the tip surface and the opening portion in the extending direction of the nozzle tip portion or at the same position as the opening portion.

In addition, the present specification discloses a component mounter including the suction nozzle described above and a component supply device that supplies the component.

### Advantageous Effects

In the suction nozzle and the component mounter disclosed in the present specification, the elastic tubular member provided on the outer periphery of the nozzle tip portion elastically deforms and adheres so as to conform to the uneven shape of the pickup surface when the tip surface thereof is pressed against the pickup surface of the component, thereby a leak of negative pressure air is suppressed. As a result, the suction nozzle can reliably and stably pick up the component having an uneven shape on the pickup surface.

### BRIEF DESCRIPTION OF DRAWINGS

FIG. 1 is a plan view illustrating an overall configuration of a component mounter including a suction nozzle of a first embodiment.

FIG. 2 is a front view of an interposer component that is an example of a component having an uneven shape on a pickup surface.

FIG. 3 is a perspective view of the suction nozzle as viewed from an obliquely lower side.

FIG. 4 is an enlarged front partial cross-sectional view of a part of the suction nozzle.

FIG. 5 is a perspective view illustrating a nozzle tip portion with solid lines and an elastic tubular member with dashed lines.

FIG. 6 is a plan view illustrating a positional relationship between the suction nozzle and the interposer component during pickup process.

FIG. 7 is a front partial cross-sectional view illustrating a state in which the suction nozzle is held by a nozzle holding section on a lower side of a mounting head.

FIG. 8 is a front partial cross-sectional view illustrating a state in which the suction nozzle picks up the interposer component.

FIG. 9 is a partially enlarged view of FIG. 8.

FIG. 10 is a plan view schematically illustrating a positional relationship between a suction nozzle including one set of a nozzle tip portion and an elastic tubular member and one abutting surface, and an odd-shaped component during pickup process in a first application example of the first embodiment.

FIG. 11 is a plan view schematically illustrating a positional relationship between a suction nozzle including two sets of nozzle tip portions and elastic tubular members and two abutting surfaces, and an odd-shaped component during pickup process in a second application example of the first embodiment.

FIG. 12 is a perspective view of a suction nozzle of a second embodiment as viewed from an obliquely lower side.

FIG. 13 is a front partial cross-sectional view illustrating a state in which the suction nozzle of the second embodiment picks up an interposer component.

### DESCRIPTION OF EMBODIMENTS

### 1. Overall Configuration of Component Mounter 1

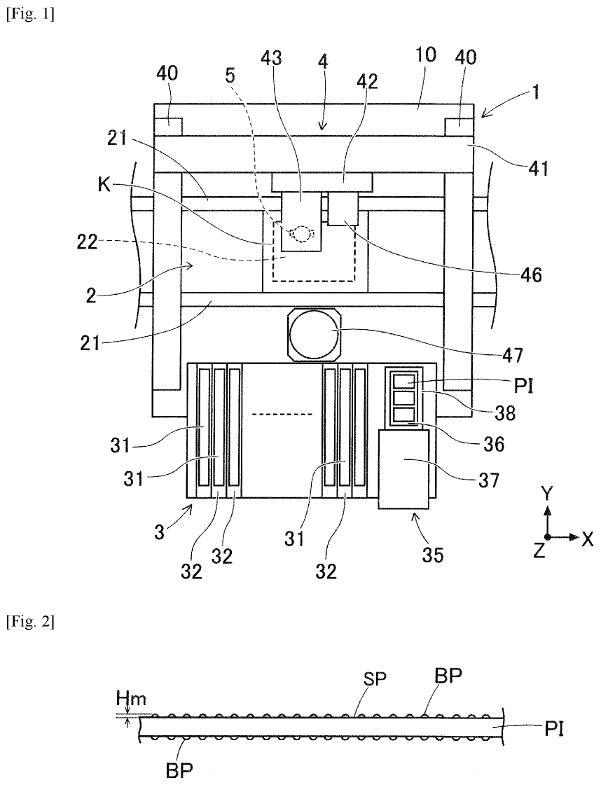

First, an overall configuration of component mounter 1 including suction nozzle 5 of a first embodiment will be described with reference to FIG. 1. Component mounter 1 performs mounting work for mounting a component on board K. A horizontal direction from a left side toward a right side on the drawing surface in FIG. 1 in which board K is conveyed is an X-axis direction, a horizontal direction from a lower side (front side) toward an upper side (rear side) on the drawing surface is a Y-axis direction, and a vertical direction is a Z-axis direction. Component mounter 1 includes board conveyance device 2, component supply device 3, component transferring device 4, base 10, control device (not illustrated), and the like.

Board conveyance device 2 includes pair of guide rails 21, a pair of conveyance belts (not illustrated), clamp mechanism 22, and the like. Pair of guide rails 21 extend in the X-axis direction across a slightly rear side of an upper surface of base 10 and are assembled to base 10 in parallel with each other. The pair of conveyance belts rotate along guide rails 21 in a state in which two parallel sides of board K are placed, and convey board K into a work performing position in the vicinity of the center of base 10. Clamp mechanism 22 pushes up conveyed board K, clamps board K with guide rails 21, and positions board K. After the mounting work of the component by component transferring device 4 ends, clamp mechanism 22 releases board K, and the conveyance belt conveys board K to the outside of the machine.

Component supply device 3 supplies a component to be mounted on board K. Component supply device 3 has multiple tape feeders 31 and tray type feeder 35. Each of multiple tape feeders 31 is set in slot 32. Tape feeder 31 pitch-feeds a carrier tape in which a large number of small-sized components are housed, and supplies pickable the small-sized components. Tray type feeder 35 is disposed side by side in the X-axis direction of tape feeder 31. Tray type feeder 35 pulls tray 36 on which the large-sized component is placed from housing magazine 37 onto table 38, and supplies pickable the large-sized component. Tray type feeder 35 supplies interposer component PI, which is an example of the large-sized component.

Component transferring device 4 includes pair of guide rails 40, Y-axis moving body 41, X-axis moving body 42, mounting head 43, suction nozzle 5, board recognition camera 46, component recognition camera 47, and the like. Pair of guide rails 40 are disposed on a left edge and a right edge of base 10 and extend in the Y-axis direction in parallel with each other while being separated from each other. Y-axis moving body 41 is formed of a member long in the X-axis direction and is mounted on pair of guide rails 40. Y-axis moving body 41 is driven by a Y-direction driving mechanism (not illustrated) to move in the Y-axis direction. X-axis moving body 42 is mounted on Y-axis moving body 41, is driven by an X-direction driving mechanism (not illustrated) to move in the X-axis direction.

Mounting head 43 is provided on a front surface of X-axis moving body 42 and is disposed above board conveyance device 2 and component supply device 3. Mounting head 43 moves in two horizontal directions together with X-axis moving body 42. Suction nozzle 5 is exchangeably provided below mounting head 43. Suction nozzle 5 performs a pickup process for picking up interposer component PI from tray type feeder 35 and a mounting process for conveying interposer component PI and mounting it at a predetermined mounting position of board K. In a case where a type of board K is changed, and the pickup process and the mounting process of interposer component PI become unnecessary, suction nozzle 5 is exchanged with a nozzle tool (not illustrated). The nozzle tool has multiple small-sized suction nozzles to perform the pickup process and the mounting process of small-sized components supplied from tape feeder 31.

Board recognition camera 46 is provided on X-axis moving body 42 alongside mounting head 43. Board recognition camera 46 is disposed such that an optical axis is directed downward, and images a position reference mark attached to board K from above. The acquired image data is subjected to image processing, so that the work performing position of board K is accurately obtained. Furthermore, the mounting position on board K where interposer component PI is mounted is calibrated. Examples of board recognition camera 46 include a digital imaging device having an imaging element such as a Charge Coupled Device (CCD) or a Complementary Metal Oxide Semiconductor (CMOS).

Component recognition camera 47 is provided on base 10 between board conveyance device 2 and component supply device 3. Component recognition camera 47 is disposed such that an optical axis is directed upward. Component recognition camera 47 images and recognizes interposer component PI held by suction nozzle 5 and the small-sized components held by multiple small-sized suction nozzles from below while mounting head 43 moves from component supply device 3 to board K. As a result, the correctness of the types of interposer component PI and small-sized component is determined, and a pickup posture of the component is detected and reflected in the mounting process. As component recognition camera 47, a digital imaging device having an imaging element such as a CCD or a CMOS can be exemplified.

A control device (not illustrated) is assembled to base 10, and an installation position thereof is not particularly limited. The control device includes a computer device having CPU and operated with software. The control device may be configured such that multiple CPUs are distributed and disposed in the device and connected in communication with each other. The control device controls board conveyance device 2, component supply device 3, and component transferring device 4 and proceeds the pickup process and the mounting process of various components, based on mounting work data created for each type of board K. The mounting work data is data describing a detailed procedure of the mounting work, a method of performing the mounting work, or the like.

### 2. Configuration of Suction Nozzle 5 of First Embodiment

Next, a configuration of suction nozzle 5 of the first embodiment will be described with reference to FIG. 2 to FIG. 7. A component having an uneven shape on the pickup surface is a pickup target of suction nozzle 5. Interposer component PI illustrated in FIG. 2 is an example of the component having an uneven shape on the pickup surface and will be described below. In a board product used in a cellular phone such as a smartphone or a similar portable information device, a structure in which two boards K disposed in parallel and close to each other are connected by interposer component PI (sometimes referred to as an interposer board) is frequently used. Interposer component PI has a rectangular thin plate shape corresponding to a small board and is larger than a general square electronic component. In addition, interposer component PI has a large number of conductors that penetrate the front and back surfaces. Hemispherical bump BP is formed at an end portion of each of the conductors. Bump BP corresponds to the protrusion shape of pickup surface SP, and the plane between adjacent bumps BP corresponds to the recessed shape of pickup surface SP. Maximum height Hm of bump BP corresponds to maximum height Hm of the uneven shape of pickup surface SP.

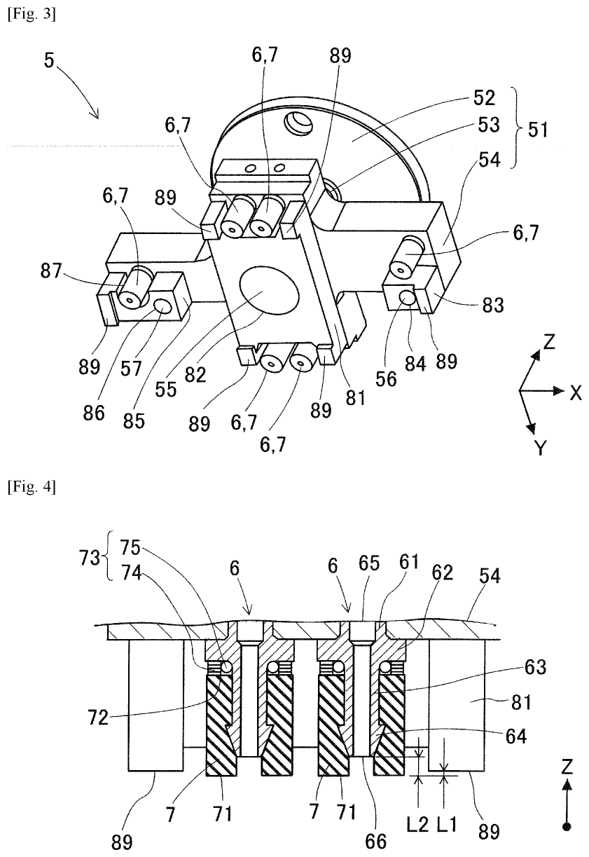

As illustrated in FIG. 3, suction nozzle 5 includes nozzle main body portion 51, six sets of nozzle tip portions 6 and elastic tubular members 7, three abutting members (81, 83, 85), and the like. Nozzle main body portion 51 is made of metal and is formed by integrally connecting attachment flange portion 52, shaft portion 53, and attachment seat portion 54 in this order from the upper side in the Z-axis direction in a use state of being held by mounting head 43. Attachment flange portion 52 is formed in a circular plate shape extending in the horizontal direction and is a portion held by mounting head 43. Shaft portion 53 is formed in a cylindrical shape having a smaller diameter than attachment flange portion 52.

Attachment seat portion 54 has a substantially cross shape that is long in the X-axis direction in plan view. Attachment seat portion 54 has relatively large circular fitting seat 55 protruding downward from the center of the lower surface thereof. Furthermore, attachment seat portion 54 has relatively small circular fitting seat 56 protruding downward from the vicinity of one end in the X-axis direction of the lower surface thereof and relatively small circular fitting seat 57 protruding downward from the vicinity of the other end in the X-axis direction.

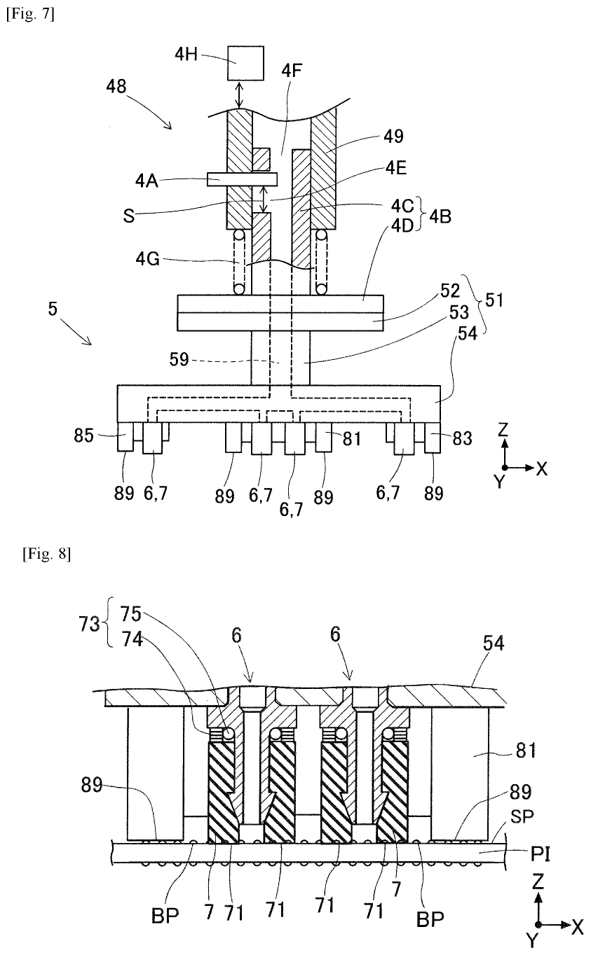

As illustrated in FIG. 7, main body flow path 59 is provided inside nozzle main body portion 51. An upstream end of main body flow path 59 is opened upward at the center of attachment flange portion 52 and communicates with air flow path 4F (described later) provided in nozzle holding section 48 of mounting head 43. A downstream side of main body flow path 59 is branched inside attachment seat portion 54 and communicates with six nozzle tip portions 6. Main body flow path 59 supplies the negative pressure air supplied from air flow path 4F during the pickup process to six nozzle tip portions 6. Furthermore, main body flow path 59 supplies the positive pressure air supplied from air flow path 4F during the mounting process to six nozzle tip portions 6.

Three abutting members (81, 83, 85) are disposed below attachment seat portion 54. First abutting member 81 is formed in a substantially rectangular shape in plan view and has abutting surfaces 89 at four apex positions of the rectangular shape, respectively. Specifically, abutting member 81 has a substantially rectangular parallelepiped-shaped outer shape that extends in the X-axis direction and the Y-axis direction and is thin in the Z-axis direction. Abutting member 81 is fixed to the center of the lower surface of attachment seat portion 54 by fitting circular fitting hole 82 provided at the center of abutting member 81 into fitting seat 55. At four corners of abutting member 81, portions protruding in the Y-axis front direction or the Y-axis rear direction from a side surface of the rectangular parallelepiped shape and further protruding downward in the Z-axis direction are integrally provided. The tip surface (lower end surface) of this portion is a square or rectangular shape and serves as abutting surface 89 that abuts against pickup surface SP (bump BP) of interposer component PI.

Second abutting member 83 has a substantially rectangular parallelepiped shape smaller than first abutting member 81. Abutting member 83 is fixed to the vicinity of one end in the X-axis direction of the lower surface of attachment seat portion 54 by fitting circular fitting hole 84 provided at the center of abutting member 83 into fitting seat 56. A portion protruding downward in the Z-axis direction is integrally provided on an outer end of abutting member 83 in the X-axis direction. The tip surface of this portion is a rectangular shape and serves as abutting surface 89 that abuts against pickup surface SP. That is, abutting member 83 has one abutting surface 89.

Third abutting member 85 has a substantially rectangular parallelepiped shape smaller than first abutting member 81. Abutting member 85 is fixed to the vicinity of the other end in the X-axis direction of the lower surface of attachment seat portion 54 by fitting circular fitting hole 86 provided on the inner side in the X-axis direction of abutting member 85 into fitting seat 57. A portion protruding downward in the Z-axis direction is integrally provided on an outer end of abutting member 85 in the X-axis direction. The tip surface of this portion is a rectangular shape and serves as abutting surface 89 that abuts against pickup surface SP. That is, abutting member 85 has one abutting surface 89. Abutting member 85 has semi-cylindrical notch portion 87 in a part of the rectangular parallelepiped shape as a space for disposing nozzle tip portion 6 and elastic tubular member 7. The shape of each of six abutting surfaces 89 in total is not limited to the square or rectangular shape described above and may be another shape such as a circle. In addition, it is preferable that the material of abutting members (81, 83, 85) or abutting surface 89 has a higher rigidity than elastic tubular member 7. As the material of abutting members (81, 83, 85) or abutting surface 89, for example, urethane rubber can be used to prevent bump BP from being damaged when it abuts against interposer component PI.

Six sets of nozzle tip portions 6 and elastic tubular members 7 have the same shape and are disposed below attachment seat portion 54. Four sets of nozzle tip portions 6 and elastic tubular members 7 are disposed side by side in the X-axis direction such that two sets are provided at each of two positions between two abutting surfaces 89 that are disposed to be separated in the X-axis direction in first abutting member 81. Fifth set of nozzle tip portion 6 and elastic tubular member 7 is disposed in the vicinity of second abutting member 83. Sixth set of nozzle tip portion 6 and elastic tubular member 7 is disposed such that about half of them enter notch portion 87 of third abutting member 85.

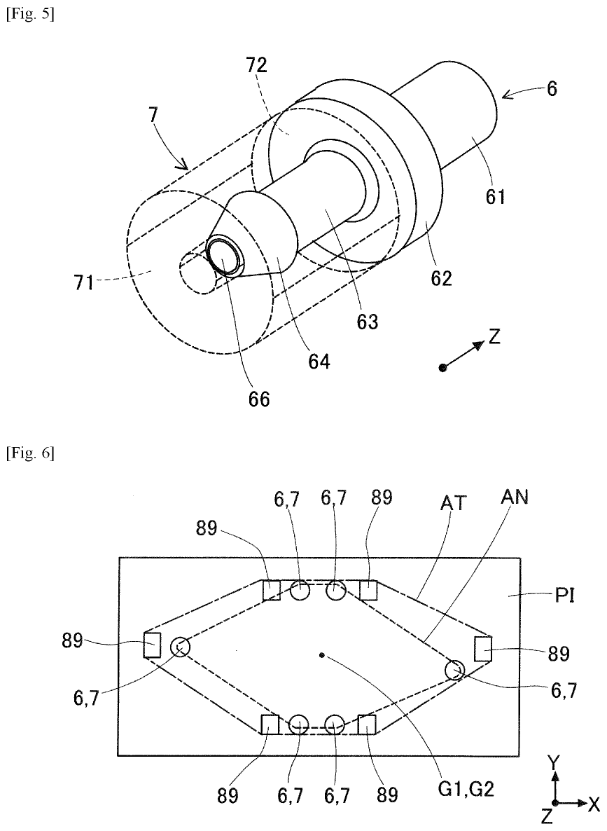

Each of nozzle tip portion 6 and elastic tubular member 7 has a rotational symmetry shape. In a use state in which suction nozzle 5 is held by mounting head 43, an extending direction of nozzle tip portion 6 coincides with the Z-axis direction (vertical direction) downward. Nozzle tip portion 6 is made of ceramics or metal. As illustrated in FIG. 4 and FIG. 5, nozzle tip portion 6 is formed by integrally connecting large diameter shaft portion 61, flange portion 62, small diameter shaft portion 63, and conical portion 64 in this order from the upper side in the extending direction.

Large diameter shaft portion 61 is a cylindrical portion. Large diameter shaft portion 61 is fitted into and fixed to attachment seat portion 54 to secure an airtight state. Flange portion 62 is a circular plate-shaped portion extending in a radially outer side and in the horizontal direction further than with respect to large diameter shaft portion 61. Small diameter shaft portion 63 is a cylindrical portion having a smaller diameter than large diameter shaft portion 61. Conical portion 64 has a conical surface on the outer peripheral side and a cylindrical surface on the inner peripheral side. An upper portion of conical portion 64 has an outer diameter larger than small diameter shaft portion 63 and protrudes radially outer side from small diameter shaft portion 63. A lower portion of conical portion 64 has a smaller outer diameter than small diameter shaft portion 63.

Internal flow path 65 is provided to penetrate the centers of large diameter shaft portion 61, flange portion 62, small diameter shaft portion 63, and conical portion 64 in the extending direction. An upper end of internal flow path 65 communicates with main body flow path 59 of attachment seat portion 54 (nozzle main body portion 51). A lower end of internal flow path 65 is an opening portion 66 that is opened at a lower end of conical portion 64. Opening portion 66 of each of six nozzle tip portions 6 is simultaneously supplied with negative pressure air from main body flow path 59.

Elastic tubular member 7 is formed in a thick cylindrical shape using an elastic material. As the elastic material, synthetic rubber such as chloroprene rubber can be exemplified, and the present disclosure is not limited to this. An inner diameter of elastic tubular member 7 is smaller than an outer diameter of small diameter shaft portion 63 of nozzle tip portion 6. Elastic tubular member 7 is inserted from conical portion 64 of nozzle tip portion 6 toward flange portion 62, and is detachably attached and adheres to the outer peripheries of small diameter shaft portion 63 and conical portion 64. At this time, since elastic tubular member 7 is elastically deformed to be slightly pushed and expanded by small diameter shaft portion 63 and greatly pushed and expanded by conical portion 64, the movement in the extending direction is prevented. In addition, elastic tubular member 7 secures airtightness at a location where it adheres to conical portion 64. Elastic tubular member 7 extends in the extending direction of nozzle tip portion 6 from opening portion 66 of nozzle tip portion 6. That is, lower tip surface 71 of elastic tubular member 7 in the extending direction is positioned below opening portion 66.

Elastic tubular member 7 has an individual difference in a length in the extending direction. Furthermore, elastic tubular member 7 may be repetitively elastically deformed to cause fatigue (permanent set), so that elastic tubular member 7 may be permanently deformed to change the length in the extending direction. Therefore, position adjustment section 73 for adjusting the position of tip surface 71 of elastic tubular member 7 is provided. As illustrated in FIG. 4, position adjustment section 73 is disposed between rear end surface 72 of elastic tubular member 7 and flange portion 62 of nozzle tip portion 6. Position adjustment section 73 includes multiple shim members 74 and O-ring 75.

Shim member 74 is a circular thin plate-shaped member having a predetermined thickness (for example, 0.1 mm). The number of shim members 74 to be used in an overlapping manner in the extending direction is adjusted and shim member 74 is inserted between rear end surface 72 and flange portion 62. Specifically, the number of shim members 74 to be used is adjusted in accordance with individual differences between six elastic tubular members 7 at the time of manufacturing. Furthermore, the number of shim members 74 to be used is adjusted in accordance with a permanent deformation of elastic tubular member 7 caused by the repeated use of suction nozzle 5. O-ring 75 is disposed between the inner periphery of shim member 74 and small diameter shaft portion 63, so as to stabilize an inserted state of shim member 74. By providing the above configuration, position adjustment section 73 can constantly adjust a relative position of tip surface 71 with respect to opening portion 66 in the extending direction.

As illustrated in FIG. 4, abutting surface 89 of abutting member (81, 83, 85) is disposed higher than tip surface 71 of elastic tubular member 7. Furthermore, opening portion 66 of nozzle tip portion 6 is disposed higher than abutting surface 89. A first dimension indicating a distance between tip surface 71 and abutting surface 89 is set to L1, and a second dimension indicating a distance between tip surface 71 and opening portion 66 is set to L2. In a case where suction nozzle 5 is driven to be lowered toward interposer component PI, tip surface 71 of elastic tubular member 7 is pressed against pickup surface SP of interposer component PI and elastically deforms so as to conform to the protrusion shape of bump BP. Elastic tubular member 7 is mainly compressed and deformed until abutting surface 89 abuts against pickup surface SP.

First dimension L1 is set within a range in which elastic tubular member 7 can be elastically deformed so that tip surface 71 conforms to the protrusion shape of bump BP, and an excessively large reaction force is not generated when elastic tubular member 7 is elastically deformed. Specifically, first dimension L1 is set to about 3 to 5 times maximum height Hm of bump BP (maximum height Hm of the uneven shape). In elastic tubular member 7, not only the surface layer portion close to tip surface 71 is deformed, but a portion up to the vicinity pushed and expanded by conical portion 64 is involved in the deformation, so that the adhesion to pickup surface SP is enhanced. In a case where first dimension L1 is set to be excessively small, tip surface 71 cannot be deformed to adhere to bump BP, a gap is generated, and the negative pressure air is likely to leak. In addition, in a case where first dimension L1 is set to be excessively large, the amount of compressive deformation of elastic tubular member 7 becomes excessively large and an excessive upward reaction force is generated, so that an excessively large driving force is required to drive suction nozzle 5 to be lowered.

In addition, second dimension L2 is set within a range in which tip surface 71 can be elastically deformed to conform to the protrusion shape of bump BP and a buckling phenomenon does not occur in elastic tubular member 7. In a case where second dimension L2 is set to be excessively small, the negative pressure air is likely to leak as in the case where first dimension L1 is set to be excessively small. In addition, in a case where second dimension L2 is set to be excessively large, there is a risk of a buckling phenomenon in which elastic tubular member 7 is greatly deformed or damaged in a direction other than the extending direction.

In a case where suction nozzle 5 picks up interposer component PI, the positional relationship illustrated in FIG. 6 is established in a plane orthogonal to the extending direction of nozzle tip portion 6. FIG. 6 corresponds to a plan view of the positional relationship between interposer component PI, nozzle tip portion 6, elastic tubular member 7, and abutting surface 89. In FIG. 6, region AN having a minimum peripheral length formed by including all of opening portions 66 of six nozzle tip portions 6 is indicated by a dashed line. Region AN is substantially hexagonal, and strictly speaking, is defined by six arcs of opening portions 66 and six line segments connecting adjacent opening portions 66 to each other. Inside region AN, center of gravity G1 of interposer component PI which is a pickup target is positioned. Furthermore, centroid position G2 of region AN represents a pickup center position at which the sum of the pickup forces generated in six sets of nozzle tip portions 6 and elastic tubular members 7 equivalently acts, and coincides with center of gravity G1 of interposer component PI or is positioned in the vicinity thereof. With this configuration, the pickup force generated in six sets of nozzle tip portions 6 and elastic tubular members 7 disposed to surround center of gravity G1 cooperatively and effectively acts on center of gravity G1 of interposer component PI.

In addition, region AT having a minimum peripheral length formed by including all of six abutting surfaces 89 is indicated by a chain line. Region AT is a polygonal region defined by six line segments connecting each side of six abutting surfaces 89 and between adjacent abutting surfaces 89 to each other. Inside region AT, centroid position G2 of region AN is included. Furthermore, the center position of region AT coincides with centroid position G2 of region AN or is positioned in the vicinity thereof. Accordingly, since six abutting surfaces 89 disposed to surround centroid position G2 abut against interposer component PI, a height position and a horizontal posture when interposer component PI is picked up are stabilized.

As illustrated in FIG. 7, suction nozzle 5 is attached to the lower side of mounting head 43. Mounting head 43 has nozzle holding section 48 and lifting and lowering drive section 4H. Nozzle holding section 48 includes holding tube 49, holding flange 4B, elastic body 4G, and the like. Holding tube 49 is formed in a cylindrical shape extending in the Z-axis direction. Holding tube 49 is supported to be liftable and lowerable by mounting head 43. Restricting pin 4A protruding radially inward is provided at an intermediate position of holding tube 49 in the Z-axis direction.

Holding flange 4B is formed by integrally connecting upper cylindrical portion 4C and lower flange portion 4D. Cylindrical portion 4C is formed in a cylindrical shape extending in the Z-axis direction. Cylindrical portion 4C secures an airtight state with holding tube 49 while fitted into the inner periphery of holding tube 49. Air flow path 4F is provided to penetrate the centers of holding tube 49 and holding flange 4B in the Z-axis direction. Elongated hole 4E extending in the Z-axis direction is formed at one location in the circumferential direction of cylindrical portion 4C. Restricting pin 4A of holding tube 49 is engaged with elongated hole 4E. Elongated hole 4E is liftable and lowerable relative to restricting pin 4A within a range of stroke length S illustrated in FIG. 7.

Flange portion 4D is formed in a circular shape having the same shape and size as attachment flange portion 52 of suction nozzle 5. Flange portion 4D and attachment flange portion 52 are stacked on each other and detachably joined to each other. As a result, suction nozzle 5 is held by nozzle holding section 48. At this time, air flow path 4F communicates with main body flow path 59 of suction nozzle 5.

Elastic body 4G is a member for suppressing damage to components by exhibiting a buffer function to reduce a shock and a load value when suction nozzle 5 or another type of suction nozzle is lowered and abuts against the component. As elastic body 4G, for example, a coil spring can be used in a compressed state. Elastic body 4G is disposed on the outer periphery of cylindrical portion 4C and is inserted between the lower end surface of holding tube 49 and flange portion 4D. Elastic body 4G urges holding flange 4B (suction nozzle 5) downward with respect to holding tube 49. Elastic body 4G can change a relative height of suction nozzle 5 with respect to holding tube 49 by expanding and contracting in an up-down direction.

In FIG. 7, restricting pin 4A is positioned above elongated hole 4E, and elastic body 4G has a predetermined extension dimension. At this time, suction nozzle 5 is relatively lowered with respect to holding tube 49. Here, it is assumed that suction nozzle 5 collides with a component or an obstacle while nozzle holding section 48 and suction nozzle 5 are lowered. In this case, since an upward force acts on elastic body 4G from suction nozzle 5, elastic body 4G may contract until restricting pin 4A moves to the lower portion of elongated hole 4E. In other words, elastic body 4G can be shortened and deformed by stroke length S and contracted to a predetermined shortened dimension. In this manner, suction nozzle 5 rises relative to holding tube 49, so that the buffer function is exhibited.

Lifting and lowering drive section 4H fixed to mounting head 43 drives holding tube 49 of nozzle holding section 48 to be lifted and lowered. As a result, suction nozzle 5, which is driven to be lowered, is lowered toward interposer component PI and performs the pickup process. As lifting and lowering drive section 4H, a servomotor or a pulse motor capable of easily adjusting the driving amount with high accuracy can be used.

### 3. Pickup Process Operation of Interposer Component PI Using Suction Nozzle 5

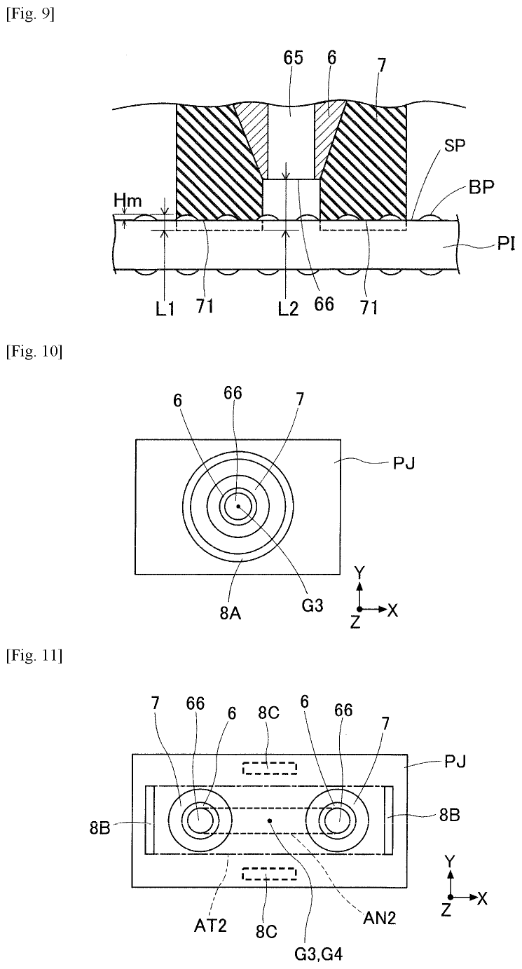

Next, an operation in which component mounter 1 performs the pickup process of interposer component PI using suction nozzle 5 will be described with reference to FIG. 8 and FIG. 9. The operation of the pickup process is proceeded by control of the control device. First, the control device moves mounting head 43 to an upper side of tray type feeder 35, and positions suction nozzle 5 above interposer component PI. Next, the control device causes lifting and lowering drive section 4H to lower nozzle holding section 48 and suction nozzle 5.

At a time when nozzle holding section 48 starts to be lowered, elastic body 4G has a predetermined extension dimension. When nozzle holding section 48 and suction nozzle 5 are lowered and tip surface 71 of elastic tubular member 7 abuts against pickup surface SP, the elastic compression deformation of elastic tubular member 7 and the shortening deformation of elastic body 40 proceed in parallel thereafter. The ratio of deformation of elastic tubular member 7 and elastic body 4G depends on the magnitude of the elastic strength of both.

On a side of elastic tubular member 7, in a case where tip surface 71 abuts against pickup surface SP, elastic deformation conforming to bump BP of elastic tubular member 7 starts. The elastic deformation of elastic tubular member 7 is continued until abutting surface 89 abuts against bump BP (protrusion shape) of pickup surface SP. That is, elastic tubular member 7 is compressed and deformed by an amount obtained by subtracting maximum height Hm of bump BP from first dimension L1, while tip surface 71 thereof is deformed conforming to bump BP, and adheres to the uneven shape of pickup surface SP. As a result, the inside of elastic tubular member 7 is in an airtight state and is in a state in which the inside is communicated with internal flow path 65 of nozzle tip portion 6.

The control device supplies the negative pressure air to the inside of elastic tubular member 7 through air flow path 4F, main body flow path 59, internal flow path 65, and opening portion 66 after or before the inside of elastic tubular member 7 is in the airtight state. As a result, suction nozzle 5 can stably pick up interposer component PI with the opening portions of tip surfaces 71 of six elastic tubular members 7. Furthermore, suction nozzle 5 stably maintains interposer component PI in a horizontal state with six abutting surfaces 89 and makes the height position constant. Thus, the pickup process of suction nozzle 5 ends.

On the other hand, at a time point when abutting surface 89 abuts against pickup surface SP, elastic body 4G has an intermediate dimension between the shortened dimension and the extension dimension. Therefore, elastic body 4G still has a buffer function of shortening and deforming from the intermediate dimension to the shortened dimension. Therefore, even though holding tube 49 (nozzle holding section 48) is further driven to be lowered after abutting surface 89 abuts against pickup surface SP, elastic body 4G is shortened and deformed, and suction nozzle 5 rises relative to holding tube 49. As a result, the buffer function of elastic body 4G is exhibited, the load applied to interposer component PI is reduced, and the damage to interposer component PI is suppressed.

Thereafter, the control device causes lifting and lowering drive section 4H to raise suction nozzle 5 to which interposer component PI is picked up. Furthermore, the control device moves suction nozzle 5 to an upper side of board K, causes lifting and lowering drive section 411 to lower suction nozzle 5, and supplies positive pressure air. As a result, suction nozzle 5 mounts interposer component PI to board K. At the time of the mounting process, the buffer function of elastic body 4G is exhibited again.

Elastic body 4G is also commonly applied to other types of suction nozzles. Therefore, the elastic strength of elastic tubular member 7 is set in accordance with the elastic strength of elastic body 4G such that the buffer function of elastic body 4G is reliably exhibited for interposer component PI. That is, the material of elastic tubular member 7 is selected compatible with the elastic strength of elastic body 4G, and the shape and dimension of elastic tubular member 7 are set.

### 4. Application Example of First Embodiment

The component, which is a pickup target of suction nozzle 5, is not limited to interposer component PI and includes odd-shaped component PJ having a hole or an uneven shape on the pickup surface, such as a switch component or a connector component. The number, dimensions, disposition, and the like of nozzle tip portion 6, elastic tubular member 7, and abutting surface 89 of suction nozzle 5 can be appropriately changed in accordance with the size, shape, and weight of odd-shaped component PJ which is a pickup target.

For example, in a first application example illustrated in FIG. 10, suction nozzle 5 includes one set of nozzle tip portion 6 and elastic tubular member 7, and one abutting surface 8A. In this aspect, center of gravity G3 of odd-shaped component PJ is configured to be positioned inside opening portion 66 of nozzle tip portion 6. Furthermore, abutting surface 8A is formed in an annular shape or a C-shape, and opening portion 66 of nozzle tip portion 6 is included inside abutting surface 8A.

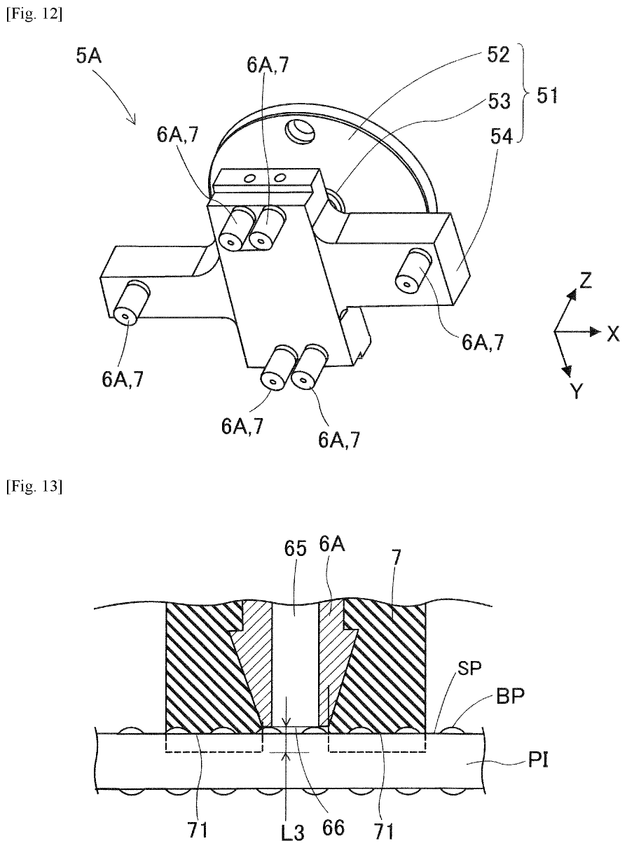

Next, in a second application example illustrated in FIG. 11, suction nozzle 5 includes two sets of nozzle tip portions 6 and elastic tubular members 7, and two abutting surfaces 8B. In this aspect, center of gravity G3 of odd-shaped component PJ is configured to be positioned inside region AN2 (indicated by the dashed line) having a narrow band shape with a minimum peripheral length formed by including opening portions 66 of two nozzle tip portions 6. Centroid position G4 of region AN2 corresponds to a pickup center position as described above and substantially coincides with center of gravity G3 of odd-shaped component PJ. Centroid position G4 of region AN2 is included inside rectangular region AT2 (indicated by the chain line) having a minimum peripheral length formed by including two abutting surfaces 8B. Suction nozzle 5 may include two abutting surfaces 8C disposed at positions indicated by dashed lines with thick lines instead of two abutting surfaces 8B.

In addition, suction nozzle 5 may include one set of nozzle tip portion 6 and elastic tubular member 7, and multiple abutting surfaces 89. In this aspect, center of gravity G3 of odd-shaped component PJ is configured to be positioned inside opening portion 66 of nozzle tip portion 6. Furthermore, opening portion 66 of nozzle tip portion 6 is included inside a region having a minimum peripheral length formed by including all of multiple abutting surfaces 89.

In addition, suction nozzle 5 may include multiple sets of nozzle tip portions 6 and elastic tubular members 7, and one abutting surface 89. In this aspect, center of gravity G3 of odd-shaped component PJ is configured to be positioned inside a region having a minimum peripheral length formed by including all of multiple opening portions 66 of nozzle tip portions 6. Furthermore, the centroid position of a region having a minimum peripheral length formed by including all of opening portions 66 of multiple nozzle tip portions 6 is included inside single abutting surface 89. As a specific disposition example, one abutting surface 89 is disposed to include center of gravity G3 of odd-shaped component PJ inside, and multiple sets of nozzle tip portions 6 and elastic tubular members 7 are disposed around abutting surface 89 in a rotational symmetry manner.

In addition, in the four aspects described above, the material of abutting surfaces (89, 8A, 8B, 8C) may be made of a hard plastic or a metal suitable for odd-shaped component PJ in addition to the urethane rubber described above. In each of the above aspects, the same effects as in the first embodiment can be obtained. That is, the pickup force generated in one set or multiple sets of nozzle tip portions 6 and elastic tubular members 7 effectively acts on center of gravity G3 of odd-shaped component PJ. Furthermore, the height position and the horizontal posture when odd-shaped component PJ is picked up are stabilized.

In suction nozzle 5 and component mounter 1 of the first embodiment and the application example, elastic tubular member 7 provided on the outer periphery of nozzle tip portion 6 elastically deforms so as to conform to the uneven shape (bump BP) of pickup surface SP when tip surface 71 thereof is pressed against pickup surface SP of the component (interposer component PI, odd-shaped component PJ), and adheres, thereby suppressing the leak of the negative pressure air. As a result, suction nozzle 5 can reliably and stably pick up a component (interposer component PI, odd-shaped component PJ) having an uneven shape on the pickup surface.

### 5. Suction Nozzle 5A of Second Embodiment

Next, suction nozzle 5A of a second embodiment will be described with reference to FIG. 12 and FIG. 13 mainly on points different from the first embodiment. In the first embodiment, nozzle tip portion 6 and abutting member (81, 83, 85) are separately provided. In the second embodiment, as illustrated in FIG. 12, suction nozzle 5A has six sets of nozzle tip portions 6A and elastic tubular members 7 on the lower side of attachment seat portion 54 of nozzle main body portion 51, and three abutting members (81, 83, 85) are omitted. Nozzle tip portion 6A also serves as an abutting member.

Furthermore, in the second embodiment, third dimension L3 indicating a distance between tip surface 71 of elastic tubular member 7 that is not elastically deformed (indicated by dashed lines in FIG. 13) and opening portion 66 is set to be smaller than second dimension L2 of the first embodiment and is set to be about the same as or slightly larger than first dimension L1. Then, in the pickup process of interposer component PI using suction nozzle 5A, when elastic tubular member 7 is elastically deformed, opening portion 66 of nozzle tip portion 6A abuts against bump BP of pickup surface SP. That is, opening portion 66 serves the function of the abutting surface of the abutting member in addition to the function of supplying the negative pressure air inside elastic tubular member 7.

In the second embodiment, similar to the first embodiment, suction nozzle 5A can reliably and stably pick up interposer component PI. In addition, the pickup force generated in six sets of nozzle tip portions 6A and elastic tubular members 7 effectively acts on center of gravity G1 of interposer component PI. Furthermore, opening portions 66 of six nozzle tip portions 6A abut against bump BP, so that the height position and the horizontal posture when interposer component PI is picked up are stabilized.

### 6. Application and Modification of Embodiment

Position adjustment section 73 described in the first embodiment may be omitted. In addition, at least one of flange portion 62 and conical portion 64 may be omitted in nozzle tip portion 6, and large diameter shaft portion 61 and small diameter shaft portion 63 may have the same dimensions. The simplest shape of nozzle tip portion 6 has a simple tubular shape with internal flow path 65 inside and opening portion 66 at the tip. Furthermore, although elastic body 4G is provided on a side of nozzle holding section 48 in the first embodiment, it may be provided on a side of suction nozzle 5. For example, shaft portion 53 may include an outer tubular portion joined to flange portion 52 and an inner tubular portion joined to attachment seat portion 54 and sliding with respect to the outer tubular portion, and elastic body 4G expanding and contracting may be provided between flange portion 52 and attachment seat portion 54, so that the relative height of attachment seat portion 54 with respect to flange portion 52 (nozzle holding section 48) can be changed.

In addition, in the first embodiment and the application examples thereof, abutting surfaces (89, 8A, 8B, 8C) are considered as a plane, however, the configuration is not limited to this. That is, abutting surfaces (8A, 8B, 8C) may have a curved surface shape such as an SR shape (a part of a spherical surface) in accordance with the surface shape of the abutting location of interposer component PI or odd-shaped component PJ. Furthermore, in the application example of the first embodiment, abutting surfaces (8A, 8I, 8C) of suction nozzle 5 may be omitted, and nozzle tip portion 6 may be replaced with “nozzle tip portion 6A also serving as an abutting member” described in the second embodiment. In addition, suction nozzle 5 may be fixedly provided in mounting head 43, tape feeder 31 may be omitted, and dedicated component mounter 1 in which interposer component PI is only pickup target may be provided. Other various applications and modifications are possible in the first and second embodiments.

### REFERENCE SIGNS LIST

1: component mounter, 2: board conveyance device, 3: component supply device, 35: tray type feeder, 4: component transferring device, 43: mounting head, 48: nozzle holding section, 49: holding tube, 4G: elastic body, 4H: lifting and lowering drive section, 5, 5A: suction nozzle, 51: nozzle main body portion, 6, 6A: nozzle tip portion, 66: opening portion, 7: elastic tubular member, 71: tip surface, 73: position adjustment section, 81, 83, 85: abutting member, 89, 8A, 8B, 8C: abutting surface, K: board, PI: interposer component, BP: bump, SP: pickup surface, PJ: odd-shaped component, L1: first dimension, L2: second dimension, AN, AN2, AT, AT2: region having minimum peripheral length, G1: center of gravity, G2: centroid position, G3: center of gravity, G4: centroid position

1. A suction nozzle that is supplied with negative pressure air to pick up a component, the suction nozzle comprising:
at least one nozzle tip portion formed in a tubular shape;
an elastic tubular member that is detachably provided on an outer periphery of the nozzle tip portion, and that extends in an extending direction of the nozzle tip portion from an opening portion of the nozzle tip portion, the elastic tubular member being configured to elastically deform to conform to an uneven shape of a pickup surface of the component when a tip surface thereof is pressed against the pickup surface; and
at least one abutting member having an abutting surface configured to abut against the pickup surface when the tip surface is pressed against the pickup surface and the elastic tubular member is elastically deformed, the abutting surface being disposed between the tip surface and the opening portion in the extending direction of the nozzle tip portion or at the same position as the opening portion.

2. The suction nozzle according to claim 1,
wherein the elastic tubular member is provided to adhere to the outer periphery of the nozzle tip portion, and when the tip surface is elastically deformed to conform to the uneven shape of the pickup surface, an inside of the elastic tubular member is in an airtight state.

3. The suction nozzle according to claim 1,
wherein, in a plane orthogonal to the extending direction of the nozzle tip portion, a center of gravity of the component that is a pickup target is positioned inside the opening portion of single nozzle tip portion, or is positioned inside a region having a minimum peripheral length formed by including the opening portions of all of multiple nozzle tip portions.

4. The suction nozzle according to claim 1,
wherein, in a plane orthogonal to the extending direction of the nozzle tip portion, a centroid position of a region having a minimum peripheral length formed by including the opening portion of single nozzle tip portion or the opening portions of all of multiple nozzle tip portions is included inside single abutting surface or inside a region having a minimum peripheral length formed by including all of multiple abutting surfaces.

5. The suction nozzle according to claim 1,
wherein the suction nozzle has the nozzle tip portion and the abutting member that are integrally provided on a lower side, and is attached to a nozzle holding section configured to be liftable and lowerable in a component mounter.

6. The suction nozzle according to claim 1,
wherein a first dimension indicating a distance between the abutting surface and the tip surface in the extending direction of the nozzle tip portion is set within a range in which the tip surface can be elastically deformed such that the tip surface conforms to the uneven shape and an excessively large reaction force is not generated when the elastic tubular member is elastically deformed.

7. The suction nozzle according to claim 1,
wherein a second dimension indicating a distance between the tip surface and the opening portion in the extending direction of the nozzle tip portion is set within a range in which the tip surface can be elastically deformed such that the tip surface conforms to the uneven shape and a buckling phenomenon does not occur in the elastic tubular member.

8. The suction nozzle according to claim 1,
wherein the nozzle tip portion is separate from the abutting member.

9. The suction nozzle according to claim 1,
wherein the nozzle tip portion also serves as the abutting member.

10. A component mounter comprising:
the suction nozzle according to claim 1; and
a component supply device configured to supply the component.

11. The component mounter according to claim 10, further comprising:
a nozzle holding section configured to hold the suction nozzle downward in a posture in which the extending direction of the nozzle tip portion is downward;
a lifting and lowering drive section configured to drive the nozzle holding section to be lifted and lowered; and
an elastic body provided in the suction nozzle or the nozzle holding section and configured to change a relative height of the suction nozzle with respect to the nozzle holding section according to a dimension of which the elastic body expands and contracts in an up-down direction, the elastic body having a predetermined extension dimension at a time point when the nozzle holding section is driven to be lowered by the lifting and lowering drive section and the lowering of the nozzle holding section is started, and having an intermediate dimension between a predetermined shortened dimension and the extension dimension at a time point when the abutting surface abuts against the pickup surface.
